(19) United States
(12) Patent Application Publication
(10) Pub. No.: US 2002/0180314 A1
(43) Pub. Date: Dec. 5, 2002

(54) Crows foot mount

(76) Inventor: Kenneth R. Pohl, Albuquerque, NM (US)

Correspondence Address: CTS WIRELESS COMPONENTS/ CTS CORPORATION, PATENT LAW DEPARTMENT, 171 COVINGTON DRIVE, BLOOMINGDALE, IL, 60108, US

(21) Appl. No.: 09/871,411

(22) Filed: May 31, 2001

(51) Int. Cl. H02N 2/00; H01L 41/04

(52) U.S. Cl. 310/348

(57) ABSTRACT

The present invention providers a mounting device for a piezoelectric transformer including a stem section for attachment to a printed circuit board and a transformer mounting section. The transformer section includes an upper extension for contacting an upper surface of the piezoelectric transformer and a lower extension for contacting a lower surface of the piezoelectric transformer. The upper and lower extensions together define an opening for receiving a piezoelectric transformer. Also provided is a piezoelectric transformer including mounting devices according to the present invention.

### FIELD OF THE INVENTION

The field of the invention relates to piezoelectric transformers and more particularly to mounting apparatus for piezoelectric transformers.

### BACKGROUND OF THE INVENTION

The mechanical and electrical mounts for a piezoelectric transformer must be designed in a manner that does not affect the overall operating resonant frequencies associated with driving the transformer. Preferably, a mounting system is universal in nature so that the same rules of operation apply to driving the piezoelectric transformer at different resonant frequencies. Additionally, the mounting system must withstand a series of triple axis shock tests, have a minimal affect on operating resonant frequencies and efficiencies, and be able to withstand the current handling requirements of the transformer under all loading and open circuit conditions. Preferably, the mechanical mount can be used in conjunction with piezoelectric transformers that implement vias so that the cost of utilizing the piezoelectric transformer as a stand-alone module is minimal.

Presently, silver filled epoxy is being used to attach and make electrical contact between a piezoelectric transformer and a printed circuit board. This mounting technique is very successful when mounting 60 kHz transformers to printed circuit boards because of the size of the transformer mounting area. The overall loss in efficiency is approximately 3-5%. However, as the transformer's physical size become smaller, such as with 120 kHz transformers, the ability to accurately mount and make electrical contact to printed circuit boards becomes an increasingly difficult and costly process. Epoxy characteristics such as humidity limitations, current-handling limitations and mechanical strength limitations must all be taken into consideration when using the silver filled epoxy method of mounting these smaller devices.

Therefore, a need exists for a system for mounting a piezoelectric transformer directly to a printed circuit board that can be used with smaller transformers.

### SUMMARY OF THE INVENTION

The present invention provides a mounting device for a piezoelectric transformer comprising a stem section for attachment to a printed circuit board and a transformer mounting section. The transformer mounting section comprises an upper extension for contacting an upper surface of the piezoelectric transformer and a lower extension for contacting a lower surface of the piezoelectric transformer. The upper and lower extensions together define an opening for receiving a piezoelectric transformer. Also provided is a piezoelectric transformer including mounting devices according to the present invention.

### BRIEF DESCRIPTION OF THE DRAWINGS

FIG. 1 is a front, right, left and top view of a piezoelectric mounting device according to the present invention;

FIG. 2 is a perspective view of a piezoelectric transformer with mounting devices of the present invention attached thereto;

FIG. 3 is a side view of a mounting device of the present invention illustrating its ability to allow deflection in along the y-axis;

FIG. 4 is a side view of a mounting device of the present invention illustrating its ability to allow deflection in along the x-axis; and

FIG. 5 is a side view of a mounting device of the present invention illustrating its ability to allow deflection in along the z-axis.

### DETAILED DESCRIPTION OF THE PREFERRED EMBODIMENT

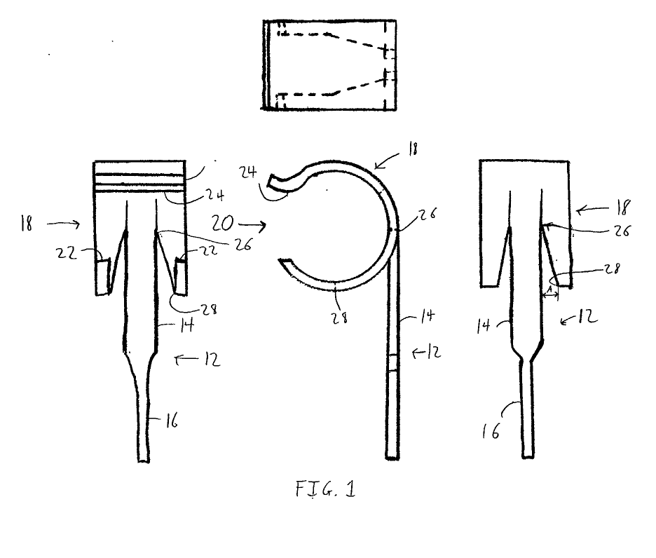

Referring to FIG. 1 there is provided a piezoelectric mounting device 10 according to the present invention. The piezoelectric mounting device 10 comprises a stem section 12 with a wide portion 14 and a narrow portion 16. The narrow portion 16 is adapted for placement in a bore defined within a printed circuit board and can be soldered or otherwise attached thereto. The piezoelectric mounting device 10 also comprises a transformer mounting section 18. The mounting section 18 is generally C-shaped and defines an opening 20 capable of receiving a piezoelectric transformer. The lower half of the C-shaped mounting section 18 comprises a pair of lower outward extensions 22, and the upper half of the C-shaped mounting section 18 comprises an upper single flared extension 24. The flared extension 24 simplifies the process of inserting a piezoelectric transformer into the opening 20 by allow the upper extension 24 to easily deflect. However, flared extensions are not preferred when an extension is to be attached with an adhesive, solder, or other attaching means. In the most preferred embodiment, the extension 24 is flared while the pair of outward extensions 22 are not flared. However, it would not depart from the present invention if the pair of extensions 22 were also flared or the extension 24 were not flared.

The pair of extensions 22 are attached to the wide portion 14 of the stem section 12 and are more preferably integral with it. Preferably, the extensions 22 also are tapered from a point below where the extensions 22 are attached to the stem section 12 such that the distance A between the extensions 22 and the stem section 12 increases as the extensions 22 extends away from the stem section 12. The taper preferably begins at point 26 below the attachment of the extensions 22 to the stem section 12 and ends at a point 28 before the end of the extensions 22. However, it would not be a departure from the present invention to provide for the taper beginning and ending at other locations or to omit the taper of the extensions 22 completely. The extension 24 is also attached to the stem section 12 and is preferably integral with it.

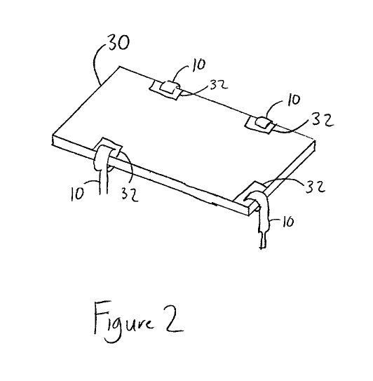

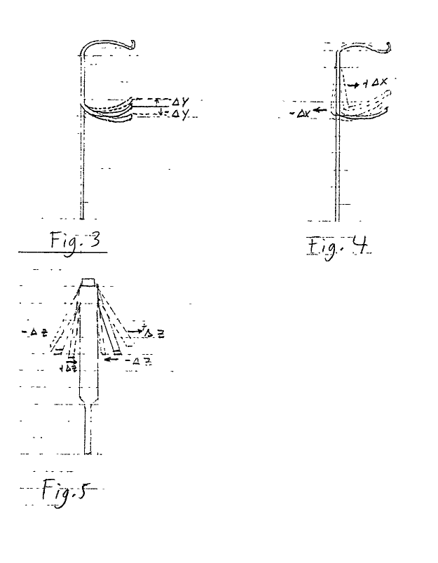

Referring to FIG. 2, the piezoelectric mounting device 10 is implemented by inserting a piezoelectric transformer 30 into the opening 20 such that the piezoelectric mounting device 10 is in contact with one of an input, output or feedback pad 32 of the piezoelectric mounting device 10. The number of mounting devices required depends on the number of pads the piezoelectric device incorporates. Preferably, the piezoelectric device is springingly maintained within the opening 20 by the extensions 22, 24. Additionally, each lower extension 22 of the mounting device 10 is soldered to its respective pad 32 to provide better mechanical and electrical contact, while the upper extension 24 is not. The location of mounting devices 10 and the pads 32 is a function of the mode in which the piezoelectric transformer operates, as is well known in the art, with the mounting devices 10 and electrical pads 32 placed at points of zero mechanical displacement of the piezoelectric transformer 30. It can be seen that the present mounting device 10 allows deflection in the y-axis (FIG. 3), in the x-axis (FIG. 4) and z-axis (FIG. 5) thereby avoiding dampening of the vibration of the piezoelectric transformer 30. Experimentation has shown that the mounting devices of the present invention decrease the efficiency of the piezoelectric device only by 3-5% and simplify the mounting process considerable in comparison to prior art methods of attaching a piezoelectric transformer to a printed circuit board.

A specific embodiment of an apparatus according to the present invention has been described for the purpose of illustrating the manner in which the invention can be made and used. It should be understood that the implementation of other variations and modifications of the invention and its various aspects will be apparent to one skilled in the art, and that the invention is not limited by the specific embodiments described. Therefore, it is contemplated to cover the present invention and any and all modifications, variations, or equivalents that fall within the scope of the claims below.

I claim:

1. A mounting device for a piezoelectric transformer comprising:
a stem section for attachment to a printed circuit board; and
a transformer mounting section comprising:
an upper extension for contacting an upper surface of the piezoelectric transformer;
a lower extension for contacting a lower surface of the piezoelectric transformer; and
wherein the upper and lower extensions together define an opening for receiving a piezoelectric transformer.

2. The mounting device of claim 1 wherein the lower extension comprises a pair of lower extensions.

3. The mounting device of claim 2 wherein the pair of lower extensions each comprise a tapered portion.

4. The mounting device of claim 2 wherein the pair of lower extensions are not flared.

5. The mounting device of claim 1 wherein the transformer mounting section is generally C-shaped.

6. The mounting device of claim 1 wherein the upper extension is flared.

7. The mounting device of claim 1 wherein the lower extension is not flared.

8. The mounting device of claim 1 wherein the device is formed from a single piece of metal.

9. The mounting device of claim 1 wherein the upper and lower extensions are each capable of being deflected when the piezoelectric transformer is placed therebetween to provide a holding force upon the piezoelectric transformer.

10. A piezoelectric transformer comprising:
a piezoelectric substrate having connection pads for at least an input and output electrical connection;
a mounting device for each of the connection pads, each mounting device comprising:
a stem section for attachment to a printed circuit board; and
a transformer mounting section comprising:
an upper extension for contacting an upper surface of the piezoelectric transformer;
a lower extension for contacting a lower surface of the piezoelectric transformer; and
wherein the upper and lower extensions together define an opening for receiving a piezoelectric transformer
wherein the mounting devices are the sole means of mechanical support and electrical connection for the piezoelectric transformer to a printed circuit board.

11. The piezoelectric transformer of claim 10 wherein the lower extension is soldered to the piezoelectric transformer.

12. The piezoelectric transformer of claim 10 wherein the lower extension comprises a pair of lower extensions.

13. The piezoelectric transformer of claim 12 wherein the pair of lower extensions is soldered to the piezoelectric transformer.

14. The piezoelectric transformer of claim 13 wherein the pair of lower extensions each comprise a tapered portion.

15. The piezoelectric transformer of claim 12 wherein the pair of lower extensions are not flared.

16. The piezoelectric transformer of claim 10 wherein the transformer mounting section is generally C-shaped.

17. The piezoelectric transformer of claim 10 wherein the upper extension is flared.

18. The piezoelectric transformer of claim 10 wherein the lower extension is not flared.

19. The piezoelectric transformer of claim 10 wherein the device is formed from a single piece of metal.

20. A mounting device for a piezoelectric transformer comprising:
a stem section for attachment to a printed circuit board; and
a C-Shaped transformer mounting section comprising:
a flared upper extension for contacting an upper surface of the piezoelectric transformer;
a pair of nonflared lower extension for contacting a lower surface of the piezoelectric transformer, each lower extension comprising a tapered portion;
wherein the upper and lower extensions together define an opening for receiving a piezoelectric transformer; and
wherein the upper and lower extensions are each capable of being deflected when a piezoelectric transformer is placed therebetween to provide a holding force upon the piezoelectric transformer.
